(19) United States
(12) Patent Application Publication
(10) Pub. No.: US 2016/0340510 A1
(43) Pub. Date: Nov. 24, 2016

(54) SILICON RESIN COMPOSITION, AND TRANSPARENT OPTICAL FILM AND PACKAGING MATERIALS MANUFACTURED THEREBY

(71) Applicant: CPC Corporation, Taiwan, Taipei City (TW)

(72) Inventors: Jen-Hsien Huang, Kaohsiung City (TW); Jui-Hsiung Huang, Kaohsiung City (TW); Chiu-Ping Li, Kaohsiung City (TW); Wen-Yen Chiu, Taipei City (TW)

(21) Appl. No.: 14/818,686

(22) Filed: Aug. 5, 2015

(30) Foreign Application Priority Data
May 18, 2015 (TW) 104115710

(51) Int. Cl. C08L 83/04; H01L 33/56; C08L 33/08

(52) U.S. Cl. CPC C08L 83/04; C08L 33/08; H01L 33/56; C08L 2203/16; C08L 2203/206; C08L 2201/10

(57) ABSTRACT

A silicon resin composition, transparent optical film, and packaging materials manufactured thereby are provided. The silicon resin composition has (A) silicone and (B) metal oxide-polymer oligomer particles. The (B) metal oxide-polymer oligomer particles are in the amount of 0.5 to 5 wt % of the total weight of the silicon resin composition. The silicon resin composition has the property of low thermal stress, high refractive index, transparency, heat resistance and good adhesion, and can be widely used in different applications.

### CROSS-REFERENCE TO RELATED APPLICATIONS

The present application claims priority of Application No. 104115710, filed in Taiwan, R.O.C. on May 18, 2015 under 35 U.S.C. §119, the entire contents of which are hereby incorporated by reference.

### BACKGROUND OF THE INVENTION

1. Field of the Invention

The present disclosure relates to a silicon resin composition, particularly a silicon resin composition with metal oxide-polymer oligomer particles and transparent optical film as well as packaging materials manufactured thereby.

2. Description of the Related Art

Silicone and epoxy are common packaging materials currently. Silicone is a major industrial packaging material, has worse adhesion and mechanical properties than conventional epoxy, and features good anti-yellowing effect after long-term exposure to high-temperature and UV environment. Therefore, silicone has better stability in practical applications.

Silicon resin, also known as silicone, is a polymer between organic and inorganic states and has a molecular structural formula of [—Si(R)₂—O—Si(R)₂—O—]n where R is methyl or phenyl usually. In conventional packaging applications, silicon resin is divided into resin A and resin B in general. Referring to a formula, resin A with double-bond (C═C) functional groups and resin B with SiH functional groups should be mixed proportionally and heated for curing by means of catalysts such as platinum, for example. In addition to having better resistance to short-wavelength radiation and less degradation, silicone isolates near-ultraviolet light, thereby preventing it from leakage and helping ensure human health. Moreover, silicone performs well in transmittance, refractivity, and heat resistance. On the basis of refractivity, silicone is classified into two types of silicon resin. The high-refractivity silicon resin (R.I.=1.53) provides better oxygen and moisture barrier performance than low-refractivity silicon resin (R.I.=1.4), and protects a sheltered object from rust. The high-refractivity silicon resin, however, has a high hardness. This results in stress inside a material being greater and being released slowly, and might lower overall reliability because of higher differential stress between silicone and other materials encased in a component.

In summary, some drawbacks are common in existing silicone such as high refractivity and high hardness, which causes greater internal stress, is released slowly, and lowers overall reliability.

### SUMMARY OF THE INVENTION

To settle the above problems, the present disclosure provides a silicon resin composition comprising (A) silicone and (B) metal oxide-polymer oligomer particles wherein the (B) metal oxide-polymer oligomer particles are in the amount of 0.5 to 5 wt % of the total weight of the silicon resin composition.

In a preferred embodiment, the (B) metal oxide-polymer oligomer particles have polymer oligomer with glass transition temperature less than 0° C.

In another preferred embodiment, the (B) metal oxide-polymer oligomer particles have polymer oligomer with molecular weights between 1000 and 10000 g/mol.

In a further embodiment, the (B) metal oxide-polymer oligomer particles account for 0.5 to 5 wt % of the silicon resin composition.

The silicon resin composition is taken as packaging material.

The present disclosure further provides high-refractivity transparent optical film which is made from the silicon resin composition.

In a preferred embodiment, the high-refractivity transparent optical film features a refractive index, n, adjusted from 1.500 to 1.650 and optical transparency within the spectrum of visual light.

The present disclosure further provides a packaging material which is made from the silicon resin composition.

Contributing to lowered thermal stress, the silicon resin composition, which is applicable to different temperature ranges and has high refractivity and optical transparency within the spectrum of visual light, can serve as LED packaging material for better luminance, heat resistance and adhesion.

### BRIEF DESCRIPTION OF THE DRAWINGS

FIG. 1 illustrates the grain size distribution of zirconium dioxide-oligomer composite particles.

FIG. 2 illustrates a transmission electron microscope (TEM) photo for zirconium dioxide-oligomer composite particles.

FIG. 3 illustrates transmittance of zirconium dioxide-oligomer-silicone composite optical film.

FIG. 4 illustrates measured refractive indices of zirconium dioxide-oligomer-silicone composite optical film.

FIG. 5 illustrates measured modulus of zirconium dioxide-oligomer-silicone composite material.

FIG. 6 illustrates measurement for thermal expansion effect of zirconium dioxide-oligomer-silicone composite material.

### DETAILED DESCRIPTION OF THE PREFERRED EMBODIMENTS

The present disclosure describes a silicon resin composition comprising (A) silicone and (B) metal oxide-polymer oligomer particles, wherein the (B) zirconium dioxide-polymer oligomer particles are in the amount of 0.5 to 5 wt % of the total weight of the silicon resin composition. The silicon resin in the present disclosure is conventional commercial-grade silicone which is available in the market and includes, but is not limited to, silicone materials sold by Shinestu (SCR-1011A/B; SCR-1012A/B), silicone materials sold by Dow Corning (Dow Corning EG-6301; Dow Corning OE-6336; Dow Corning JCR 6175; Dow Corning SR-7010), and “InvisiSil” silicone sold by GE-Toshiba, each of which is one option used in manufacturing the silicon resin composition. Preferably, the silicone, which is characteristic of a high refractive index (R.I.=1.53) compared with another silicone with a low refractive index (R.I.=1.4), provides good oxygen and moisture barrier performance for better protection and anti-corrosion in packaging applications.

The metal oxide-polymer oligomer particles in the present disclosure refer to composite particles synthesized with metal oxide and polymer oligomer and feature controllable grain sizes by means of polymer oligomer and added acetic acid for development of a stable suspension liquid and a clear solution. The mean grain size of the metal oxide-polymer oligomer particles are between 1 and 100 nm or preferably between 2 and 50 nm or between 10 and 40 nm. In this regard, the mean grain size over 100 nm refers to opaque metal oxide-polymer oligomer particles within the spectrum of visual light, which are not ideal in applications for demands of transparent particles.

In general, the metal oxide-polymer oligomer particles are manufactured using a sol-gel method, which is a transformation process between two physical chemistry states. The sol contains active colloidal particles which have grain sizes between 1 and 100 nm and are uniformly distributed and suspended in a liquid based on Brownian movement. The gel is kept at a higher concentration by which collision-bonding actions are enabled among particles for multi-dimensional cross-link, infinite molecular weights and expected shapes when liquid solvents in the sol are vaporized constantly.

In detail, precursors such as alkoxy metal precursors for manufacture of the metal oxide-polymer oligomer particles react in an alcohol solvent and/or a ketone solvent which has an alkyl carbon number identical to that of alkoxide in order to avoid any reaction of exchanging alkoxy in alkoxide with alkyl in alkanol. When distilled water (equivalence ratio of distilled water to metal alkoxide=2) is added, the metal oxide-polymer oligomer composite particles are developed in a stable suspension liquid in which the particles' grain sizes are controlled by polymer oligomer and added acetic acid. In follow-up applications, the metal oxide-polymer oligomer particles are further manufactured when vaporization of solvents are synchronized with cross-link reactions of the sol-gel oxide in which other materials are mixed.

Preferably, the polymer oligomer (oligomer for short) in the present disclosure is based on polymer with low glass transition temperature (less than 0° C.) for lower hardness and thermal stress of overall silicone materials in a high-temperature-difference environment and higher adhesion of silicone materials in an LED light cup at room temperature. The polymer oligomer is synthesized when polymer monomers including, but not limited to, Butylacrylate, ethylene, propylene, butene, isoprene and isobutylene, react with chain transfer agents including, but not limited to, Benzenethiol, 2-Naphthalenethiol, 1-Butanethiol, Ethyl mercaptoacetate, 2-mercaptoethanol and 2-Propanetthiol in ethyl acetate or Tetrahydrofuran at a high temperature (50-80° C.). Furthermore, the molecular weights of the polymer oligomer are between 1000 and 10000 g/mol.

In the present disclosure, the silicon resin composition is prepared when the metal oxide-polymer oligomer particles mix with commercial-grade silicone B and commercial-grade silicone A sequentially, wherein silicone A and silicone B contain double-bond (C═C) functional groups and SiH functional groups, respectively. Another preparation method which refers to the metal oxide-polymer oligomer particles first being mixed with commercial-grade silicone A is not recommended herein because commercial-grade silicone A containing double-bond groups and catalyzed by platinum self-react in a follow-up process to remove solvents (vacuum volatilization in 60° C.). Additionally, the metal oxide-polymer oligomer particles can be added when commercial-grade silicone A and commercial-grade silicone B are mixed simultaneously. This preparation method, however, is not recommended because redundant solvents added with the metal oxide-polymer oligomer particles need to be removed in a vacuum concentration process at 60° C. which induces commercial-grade silicone A containing double-bond groups to react in catalysts.

The silicon resin composition in which the metal oxide-polymer oligomer particles are uniformly distributed contributes to development of polymer composites which feature good thermal stability and are appropriate for optical applications when the silicon resin composition is produced to a layer of transparent film with good thermal stability and high refractivity. The composites made from the silicon resin composition and having good transparency, refractivity, thermal stability, adhesion and reliability are applicable to different purposes, particularly high-refractivity transparent semiconductor packaging materials because of low thermal stress and high reliability.

The following embodiments should not be taken as examples to limit more applications of the present invention. Any modification or change of an embodiment in the present disclosure made by a skilled person without departing from spirit or scopes of the present invention should be incorporated in claims thereof.

### EXAMPLE 1

### Preparation of Polymer Oligomer

The example refers to the formula in Table 1. Butylacrylate (10 g), Azodiisobutyronitrile (free-radical initiator; 0.08 g) and 2-mercaptoethanol (chain transfer agent; 0.312 g) are mixed in ethyl acetate (20 g) and agitated for 48 hours in 85° C. for synthesizing polymer oligomer. The molecular weights of the oligomer measured with a Gel Permeation Chromatography (GPC) are 3983 g/mol (oligomer 1) and 2144 g/mol (oligomer 2).

TABLE 1

| | Ethyl acetate | Butylacrylate | Azodiisobutyronitrile | 2-mercaptoethanol |
|---|---|---|---|---|
| Oligomer | (g) | (M) | (M) | (M) |
| Oligomer 1 | 20 | 1.688 | 0.025 | 0.2 |
| Oligomer 2 | 20 | 1.688 | 0.25 | 0.5 |

### Embodiment: Preparation of Silicon Resin Composition with Zirconium Dioxide-oligomer Composite Particles (ZrO₂-oligomer/silicone)

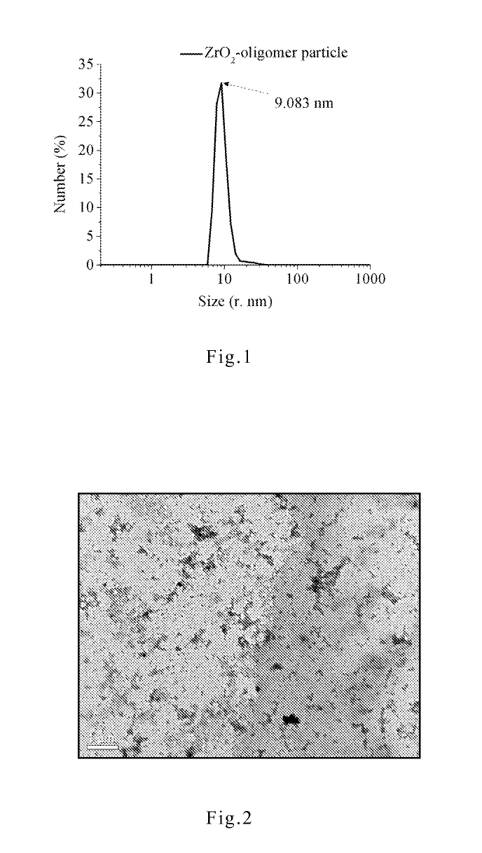

The embodiment describes the sol-gel method for preparation of zirconium dioxide-oligomer composite particles and refers to the formula in Table 2. Zirconium (IV) propoxide (ZPP) mixed with oligomer in Example 1 and acetic acid are added into butanol-butanone solvents and agitated uniformly. Distilled water (equivalence ratio of distilled water to ZPP=2) is added into the above solution for development of zirconium dioxide-oligomer composite particles and a clear transparent solution in an ultrasonic homogenizer after several minutes. The grain size distribution of zirconium dioxide-oligomer composite particles is measured with a Dynamic Light Scatter (DLS; Zetasizer nano ZS), as shown in FIG. 1. The morphology of zirconium dioxide-oligomer composite particles is checked with a Transmission Electron Microscope (TEM), as shown in FIG. 2.

As shown in Table 2, the zirconium dioxide-oligomer composite particles synthesized in the above embodiment are added into commercial-grade silicone B (Dow corning OE-6630) with high refractivity and mixed uniformly in room temperature for development of ZrO₂-oligomer-silicone B in a vacuum concentration process to remove solvents at 60° C. The silicon resin composition with zirconium dioxide-oligomer composite particles, ZrO₂-oligomer-silicone, is prepared after ZrO₂-oligomer-silicone B and commercial-grade silicone A (ZrO₂-oligomer-silicone B: silicone A=3:1) are mixed. Table 2 indicates six designations of ZrO₂-oligomer-silicone B in series: ZrO₂-oligomer 2-silicone AB1 (ZrO₂-oligomer 2-AB1 for short), ZrO₂-oligomer 2-silicone AB2 (ZrO₂-oligomer 2-AB2 for short), ZrO₂-oligomer 2-silicone AB3 (ZrO₂-oligomer 2-AB3 for short), ZrO₂-oligomer 1-silicone AB1 (ZrO₂-oligomer 1-AB1 for short), ZrO₂-oligomer 1-silicone AB2 (ZrO₂-oligomer 1-AB2 for short) and ZrO₂-oligomer 1-silicone AB3 (ZrO₂-oligomer 2-AB3 for short).

TABLE 2

| Designation of | | | Butanol/ | Acetic | Distilled | |
|---|---|---|---|---|---|---|
| ZrO₂-oligomer/ | ZPP | | butanone | acid | water | Commercial-grade |
| silicone B | (g) | Oligomer (g) | (g) | (g) | (g) | silicone B (g) |
| ZrO₂-oligomer | 3.0 | 0.4 (oligomer 2) | 20 | 1.0 | 0.5 | 60 |
| 2-B1 | | | | | | |
| ZrO₂-oligomer | 3.0 | 0.4 (oligomer 2) | 20 | 1.0 | 0.5 | 37 |
| 2-B2 | | | | | | |
| ZrO₂oligomer | 3.0 | 0.4 (oligomer 2) | 20 | 1.0 | 0.5 | 22 |
| 2-B3 | | | | | | |
| ZrO₂-oligomer | 3.0 | 0.4 (oligomer 1) | 20 | 1.0 | 0.5 | 60 |
| 1-B1 | | | | | | |
| ZrO₂oligomer | 3.0 | 0.4 (oligomer 1) | 20 | 1.0 | 0.5 | 37 |
| 1-B2 | | | | | | |
| ZrO₂-oligomer | 3.0 | 0.4 (oligomer 1) | 20 | 1.0 | 0.5 | 22 |
| 1-B3 | | | | | | |

### Experiment 1: Measuring Refractivity and Transmittance

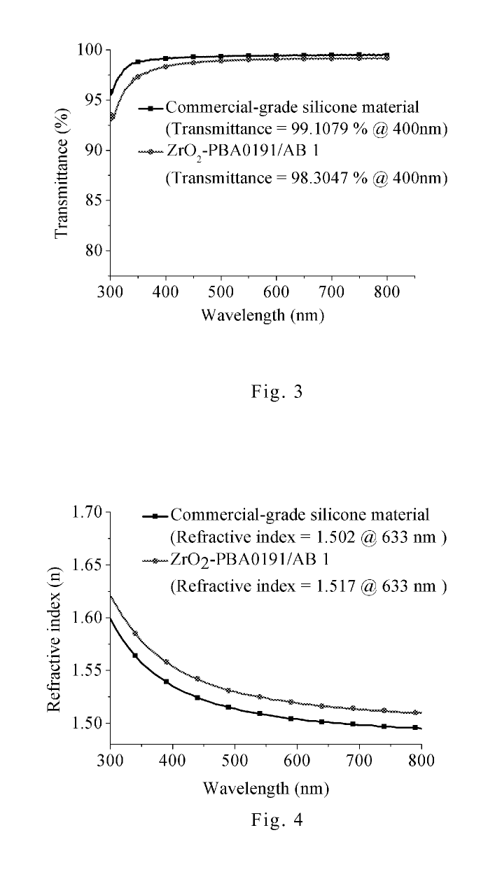

Diluted with Tetrahydrofuran and dripped on a piece of glass, the silicon resin composition with moderate zirconium dioxide-oligomer composite particles undergoes 30-minute baking at 80° C. and 1-hour high-temperature polymerization at 150° C. for development of ZrO₂-oligomer-silicone composite optical film. Refractivity and transmittance of the optical film exposed to incident rays with wavelengths from 300 to 800 nm are measured with an ellipsometer and a UV-Vis spectrometer, respectively. Experimental results of ZrO₂-oligomer 2-silicone AB1 versus commercial-grade silicone (Dow Corning OE-6630) are shown in FIGS. 3 and 4.

### Experiment 2: Measuring Material's Modulus and Coefficient of Thermal Expansion

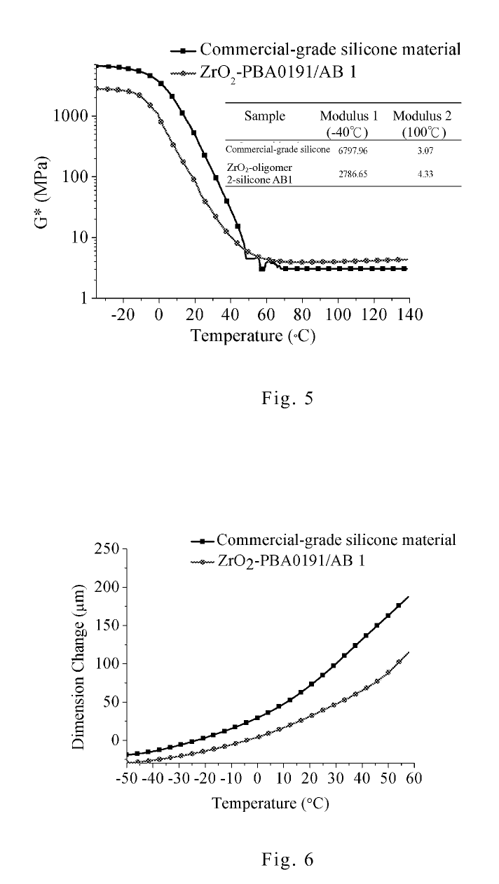

Applied on a Teflon board, the silicon resin composition with moderate zirconium dioxide-oligomer composite particles undergoes 30-minute baking at 80° C. and 1-hour high-temperature polymerization at 150° C. for synthesis of ZrO₂-oligomer-silicone composite material. The composite material's modulus and coefficient of thermal expansion are measured with a Dynamic Mechanical Analyzer (DMA) and a Thermal Mechanical Analyzer (TMA), respectively. Experimental results of ZrO₂-oligomer 2-silicone AB1 versus commercial-grade silicone (Dow Corning OE-6630) are shown in FIGS. 5 and 6.

### Experiment 3: Measuring Luminance and Reliability of Packaging Material

Instilled into a wire-bonded and encapsulated LED light cup, the silicon resin composition with moderate zirconium dioxide-oligomer composite particles undergoes various polymerization processes at 50° C. (30 minutes), 80° C. (30 minutes), 90° C. (3 hours), 110° C. (30 minutes) and 150° C. (1 hour) for synthesis of ZrO₂-oligomer-silicone composite packaging material. Luminance of LED packaging material is repeatedly measured with a CAS-140B compact-array spectrometer (Instrument Systems GmbH; 150 mA & 5 V) in high-temperature-difference cycle runs (from −35° C. to 125° C.; dwell time=15 minutes). Reliability of LED packaging material is accessed by the frequency of an LED lamp lit up in high-temperature-difference cycle runs. Experimental results for the silicon resin composition with zirconium dioxide-oligomer composite particles are shown in Table 3 (luminance) and Table 4 (high-temperature-difference cycle runs), respectively.

TABLE 3

| | Luminous flux | Increased |
|---|---|---|
| | of packaging | luminous flux |
| Sample | material (lm) | (%) |
| Commercial-grade silicone | 4.1145 | 0% |
| (Dow corning OE-6630) | | |
| ZrO₂-oligomer 2-AB1 | 4.3663 | 6.12% |
| ZrO₂-oligomer 2-AB2 | 4.2726 | 3.84% |
| ZrO₂-oligomer 2-AB3 | 4.3735 | 6.29% |

TABLE 4

| | 100 | 200 | 300 | 350 | 550 | 750 |
|---|---|---|---|---|---|---|
| Sample | cycles | cycles | cycles | cycles | cycles | cycles |
| Commercial- | 0/10 | 2/10 | 7/10 | | | |
| grade | | | | | | |
| silicone (Dow | | | | | | |
| corning | | | | | | |
| OE-6630) | | | | | | |
| ZrO₂- | 0/10 | 0/10 | 0/10 | 0/10 | 0/10 | 0/10 |
| oligomer | | | | | | |
| 2-AB1 | | | | | | |
| ZrO₂- | 0/10 | 0/10 | 0/10 | 0/10 | 0/10 | 0/10 |
| oligomer | | | | | | |
| 2-AB2 | | | | | | |
| ZrO₂- | 0/10 | 0/10 | 0/10 | 0/10 | 0/10 | 0/10 |
| oligomer | | | | | | |
| 2-AB3 | | | | | | |

As shown in the figures and tables herein, the silicon resin composition displays worse transmittance (FIG. 3) but better refractivity (FIG. 4) than those of commercial-grade silicone. It can be seen from FIGS. 5 and 6 the silicon resin composite based on the silicon resin composition has lower modulus and lower coefficient of thermal expansion than those of commercial-grade silicone and moderates high internal stress. Table 3 indicates that the silicon resin composition contributes to luminance of packaging material. Table 4 indicates ratios of the numbers of LED lamps not lit up in cycle runs (numerators) to the total numbers of LED lamps (denominators). For example, 2/10 means two of ten LED lamps made from the packaging material were not lit up, wherein each cycle run is defined as a sample tested in high-temperature-difference environment from −35° C. to 125° C. first and from 125° C. to −35° C. later. Reliability of an LED lamp which still works after running more cycles in high-temperature-difference environment is better. In this regard, LED lamps made from the silicon resin composition keep working after 750 cycle runs. This is in contrast to 7 of 10 other LED lamps made from commercial-grade silicone which failed after fewer than 300 cycle runs. Thus, the packaging material based on the silicon resin composition in the present disclosure assists a product in reliability. In summary, the ZrO₂-oligomer-silicone composition can be used in manufacturing low-thermal-stress, high-refractivity and transparent resin, which performs well in heat resistance and adhesion, promote luminance and reliability of a product packaged with the resin and lower thermal stress inside silicon resin in extensive applications.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A silicon resin composition, comprising (A) silicone and (B) metal oxide-polymer oligomer particles wherein the (B) metal oxide-polymer oligomer particles are in the amount of 0.5 to 5 wt % of the total weight of the silicon resin composition.

2. A silicon resin composition according to claim 1, wherein the (B) metal oxide-polymer oligomer particles have polymer oligomer with glass transition temperature less than 0° C.

3. A silicon resin composition according to claim 1, wherein the (B) metal oxide-polymer oligomer particles have polymer oligomer with molecular weights between 1000 and 10000 g/mol.

4. A high-refractivity transparent optical film made from the silicon resin composition in claim 1.

5. The high-refractivity transparent optical film according to claim 4, which features a refractive index adjusted from 1.500 to 1.650 and optical transparency within the spectrum of visual light.

6. A packaging material which is made from the silicon resin composition in claim 1.
